(19) United States
(12) Patent Application Publication
(10) Pub. No.: US 2026/0060063 A1
(43) Pub. Date: Feb. 26, 2026

(54) Reducing electrical resistance of electrical conductors on both sides of an electronic device

(71) Applicant: Marvell Asia Pte Ltd, Singapore (SG)

(72) Inventors: Hui Wang, Pleasanton, CA (US); Runzi Chang, Saratoga, CA (US)

(21) Appl. No.: 19/250,116

(22) Filed: Jun. 26, 2025

Related U.S. Application Data
(60) Provisional application No. 63/664,710, filed on Jun. 26, 2024.

(51) Int. Cl. H01L 23/528; H01L 21/768; H01L 23/48; H01L 23/522; H01L 23/552

(52) U.S. Cl. CPC H01L 23/528; H01L 21/76898; H01L 23/481; H01L 23/5226; H01L 23/5227; H01L 23/552

(57) ABSTRACT

An electronic device, includes (a) a semiconductor substrate, (b) a plurality of transistors formed on a first side of the semiconductor substrate, and (c) a first set of metal interconnect layers formed on the first side of the semiconductor substrate, and a second set of metal interconnect layers formed on a second side of the semiconductor substrate opposite to the first side, each of the first set and the second set of metal interconnect layers includes (i) one or more layers whose electrical resistance is in a first range of resistances, and (ii) at least one layer whose electrical resistance is in a second range of resistances, lower than the first range.

### CROSS-REFERENCE TO RELATED APPLICATIONS

This application claims the benefit of U.S. Provisional Patent Application 63/664,710, filed Jun. 26, 2024, whose disclosure is incorporated herein by reference.

### FIELD OF THE DISCLOSURE

The present invention relates generally to electronic devices, and particularly to improved methods and systems for reducing electrical resistance of electrical conductors on both sides of an electronic device.

### BACKGROUND

The ongoing miniaturization of integrated circuit (IC) technology has created substantial challenges in controlling electrical resistance and ensuring efficient power distribution. While backside power delivery (BSP) has been developed to mitigate some of these issues, BSP remains inadequate for the integration of high-performance components, especially in analog circuit designs. As a result, devices utilizing BSP may experience (i) diminished data signal quality due to heightened signal interference, and/or (ii) an undesirably larger device footprint, since increased spacing between elements such as inductors is necessary to reduce interference and noise.

The description above is presented as a general overview of related art in this field and should not be construed as an admission that any of the information it contains constitutes prior art against the present patent application.

### SUMMARY

An embodiment of the present invention that is described herein provides an electronic device, including: (a) a semiconductor substrate, (b) a plurality of transistors formed on a first side of the semiconductor substrate, and (c) a first set of metal interconnect layers formed on the first side of the semiconductor substrate, and a second set of metal interconnect layers formed on a second side of the semiconductor substrate opposite to the first side, each of the first set and the second set of metal interconnect layers includes (i) one or more layers whose electrical resistance is in a first range of resistances, and (ii) at least one layer whose electrical resistance is in a second range of resistances, lower than the first range.

In some embodiments, (a) the at least one layer configured to support circuit elements with reduced electrical resistance in the first set includes a first inductor of an analog circuit, (b) the at least one layer configured to support circuit elements with reduced electrical resistance in the second set includes a second inductor of the analog circuit, and (c) at least the one or more layers whose electrical resistance is in the first range of resistances are arranged to provide electromagnetic shielding between the first inductor and the second inductor.

In other embodiments, the first set of metal interconnect layers includes layers configured to route data signals, and the second set of metal interconnect layers includes layers configured to distribution electrical power. In yet other embodiments, the electronic device further includes a power delivery network implemented in the second set of metal interconnect layers.

In some embodiments, the at least one layer from each of the first set and the second set of metal interconnect layers is positioned as an outermost layer in its respective set. In other embodiments, the electronic device further includes multiple inductors formed in the at least one layer configured to support circuit elements with reduced electrical resistance in each of the first set and the second set of metal interconnect layers. In yet other embodiments, the multiple inductors are arranged in a stacked configuration with at least a first inductor in the first set of metal interconnect layers vertically aligned with at least a second inductor in the second set of metal interconnect layers.

In some embodiments, the electronic device further includes a plurality of through-substrate vias traversing the semiconductor substrate between the first side and the second side, the through-substrate vias being configured to conduct data signals and electrical power between (i) the plurality of transistors, and (ii) the first set and the second set of metal interconnect layers. In other embodiments, the plurality of through-substrate vias include first through-substrate vias for signal routing and second through-substrate vias for power distribution. In yet other embodiments, at least one of the first through-substrate vias is configured to conduct the data signals between the first set and the second set of metal interconnect layers.

There is additionally provided, in accordance with an embodiment of the present invention, a method for fabricating an electronic device, the method including forming a plurality of transistors on a first side of a semiconductor substrate. A first set of metal interconnect layers is formed on the first side of the semiconductor substrate. A second set of metal interconnect layers is formed on a second side of the semiconductor substrate opposite to the first side. The formation of each of the first set and the second set of metal interconnect layers includes: (i) forming one or more layers whose electrical resistance is in a first range of resistances, and (ii) forming at least one layer whose electrical resistance is in a second range of resistances, lower than the first range.

The present disclosure will be more fully understood from the following detailed description of the embodiments thereof, taken together with the drawings in which:

### BRIEF DESCRIPTION OF THE DRAWINGS

FIG. 1 is a cross-sectional view of an electronic device, in accordance with an embodiment that is described herein;

FIG. 2 is a cross-sectional view of is a cross-sectional view of an analog circuit implemented in another section a section of the electronic device of FIG. 1 with an inset showing a top view, in accordance with another embodiment that is described herein; and

FIG. 3 is a flowchart depicting a fabrication process of the analog circuit implemented in the electronic device of FIG. 2, in accordance with an embodiment that is described herein.

### DETAILED DESCRIPTION OF EMBODIMENTS

As integrated circuit (IC) technology continues to scale down, manufacturers encounter escalating challenges related to the electrical resistance of interconnects, including both metal layers and the vias that connect the metal layers. Elevated resistance can result in significant IR drops, which may restrict the number of metal levels that can be implemented on a single side of the substrate. For the purposes of this disclosure and the accompanying claims, “IR drop” refers to the voltage drop within an integrated circuit's power delivery network caused by resistance in the metal and via interconnects, which can adversely affect circuit performance and timing. These resistance-related issues are further compounded by the competition for limited layout space between power and signal wires, resulting in congested layouts and increased difficulty in maintaining process uniformity. Existing backside power solutions are limited by the absence of sufficiently thick (e.g., greater than about 0.5 μm) metal layers on the signal side, thereby restricting the integration of high-performance elements in ICs, including but not limited to analog components. Consequently, these constraints necessitate larger spacing for analog components, which increases overall chip area and heightens the risk of signal interference in high-speed IC devices.

Embodiments of the present disclosure that are described herein provide an electronic device featuring one or more integrated circuit structures that incorporate thick metal layers (e.g., with a thickness greater than about 0.5 μm) on both the front and back sides of the semiconductor substrate, with transistors formed on the front side of the substrate. In some embodiments, the electronic device comprises a first set of metal interconnect layers on the front side of the substrate and a second set of metal interconnect layers on the back side, with each set comprising layers configured to support circuit elements with reduced electrical resistance. These sets of layers are interconnected by a plurality of through-substrate vias, which facilitate efficient signal routing and robust power distribution throughout the electronic device.

In some embodiments, the electronic device comprises a semiconductor substrate with transistors formed on a first (e.g., front) side of the substrate of the electronic device. Both the first and second sets of metal interconnect layers comprise multiple layers with distinct electrical resistances. In these embodiments, at least one layer in each set is configured to have lower resistance, thereby supporting high-performance elements such as inductors. This reduced resistance can be obtained through increased thickness along the Z-axis (as described above) and/or greater width in the XY plane of the electronic device. Such an arrangement enables the implementation of analog circuits with inductors positioned on both sides of the substrate, with the intervening layers, including the substrate itself, configured for electromagnetic shielding between components. In other embodiments, this configuration can facilitate the integration of other high-performance elements, such as high-speed digital circuits in digital ICs.

In some embodiments, the disclosed techniques allow for independent optimization of metal interconnect layers dedicated to signal routing and those dedicated to power distribution. This approach provides the flexibility to implement a power delivery network predominantly on one side of the electronic device, while preserving high-performance signal routing capabilities on the opposite side. Moreover, the disclosed structure facilitates the integration of multiple inductors on both the front and back sides of the electronic device, with front side inductors being vertically aligned with corresponding back-side inductors to maximize spatial efficiency. Furthermore, the electromagnetic shielding afforded by the substrate and intervening layers effectively reduces interference between inductors implemented on opposite sides of the electronic device, thereby improving the overall electrical performance of the electronic device.

The disclosed techniques can enhance electronic devices by: (i) reducing the footprint of device blocks in designs constrained by inductor size; (ii) improving the signal-to-noise ratio in high-speed analog circuits; and (iii) enabling improved power delivery while maintaining high-performance signal routing in both analog devices and digital devices.

Moreover, the disclosed techniques introduce a novel metal scheme for the era of Backside Power, enabling low-resistance, thick metal layers for passive devices and high-speed signal routing on both sides of the electronic device. This represents a significant advancement over the current practice of utilizing thick metal only on the backside. By implementing thick metals on both sides, the performance of Serializer/Deserializer (SerDes) modules and die-to-die (D2D) modules in various electronic devices can be enhanced, as these techniques enable the implementation of key circuit elements, such as high-Q inductors, on both sides of the device.

The description above is presented as a general overview of embodiments of the present disclosure, which are described in detail herein.

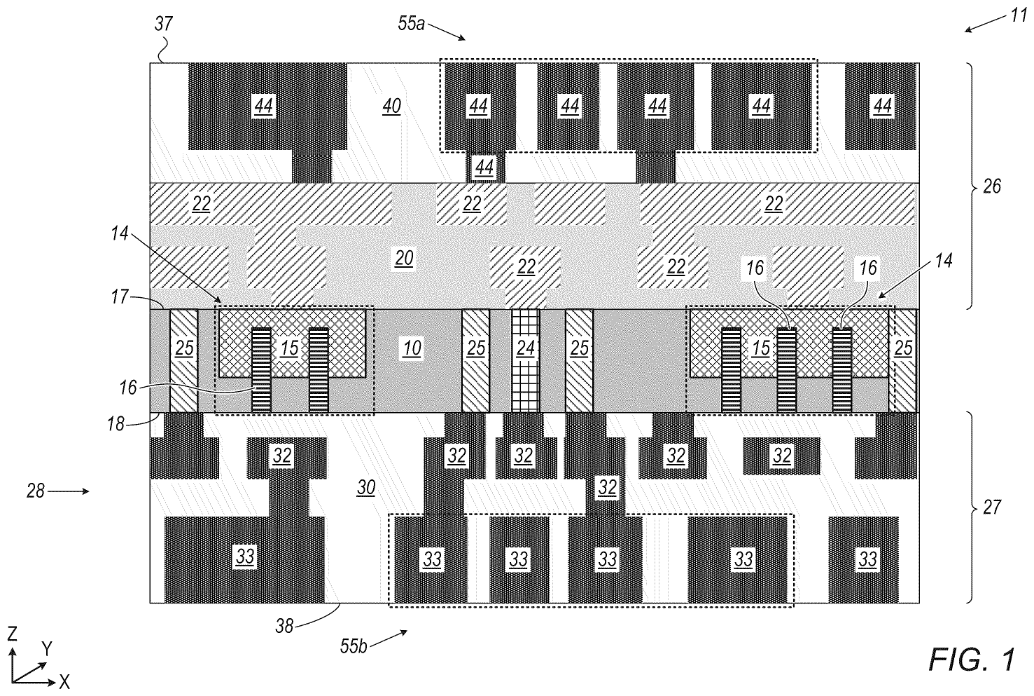

FIG. 1 is a cross-sectional view of an electronic device 11, in accordance with an embodiment that is described herein.

In some embodiments, electronic device 11 (also referred to herein as a device 11, for brevity) comprises a semiconductor substrate 10 having a first side 17 and a second side 18, also referred to herein as a front side and a back side, respectively. In some embodiments, a plurality of transistors 14 are formed on first side 17 of semiconductor substrate 10. Each transistor 14 comprises a gate 15 and source-drain regions 16. In the present example, transistors 14 are three-dimensional (3D) gate-all-around (GAA) field-effect transistors (FETs), with source and drain regions 16 implemented in nanosheets (as shown) or alternatively in nanowires. In other embodiments, at least one of the transistors 14 may be any other suitable type of transistor, including, but not limited to, a 3D finFET or a two-dimensional (2D) metal-oxide-semiconductor (MOS) FET.

In some embodiments, electronic device 11 comprises a first set 26 of metal interconnect layers formed on first side 17 (the front side) of semiconductor substrate 10, and a second set 27 of metal interconnect layers formed on second side 18 (the back side) of semiconductor substrate 10 opposite to first side 17. Electronic device 11 further comprises (i) dielectric layers 20 and 40 positioned between the various interconnect layers of the first set 26 of metal interconnect layers, and (ii) one or more dielectric layers 30 positioned between the various interconnect layers of the second set 27 of metal interconnect layers. Dielectric layers 20, 30 and 40 are configured to provide electrical isolation between the patterned metal interconnect layers.

In some embodiments, each of first set 26 of metal interconnect layers and second set 27 of metal interconnect layers comprises (i) one or more layers whose electrical resistance is in a first range of resistances, and (ii) at least one layer whose electrical resistance is in a second range of resistances, lower than the first range. The metal interconnect layers of sets 26 and 27 are typically patterned dielectric layers 20, 30 and 40. These metal interconnect layers typically comprise lines patterned in an XY plane, and vias patterned along the Z-axis and configured to connect between the metal lines. In some embodiments, at least the layers of the first set 26 of metal interconnect layers whose electrical resistance is in a first range of resistances are configured to route data signals, and at least the layers of the second set 27 of metal interconnect layers whose electrical resistance is in a first range of resistances are configured to distribute electrical power.

Reference is now made to the first set 26 of metal interconnect layers. In some embodiments, the one or more layers with the higher electrical resistance in the first range comprise signal interconnect layers 22 patterned in dielectric layer 20 and configured to exchange data signals with transistors 14 and other components described below. The at least one layer with the lower electrical resistance, i.e., in the second range, comprises one or more power interconnect layers 44 patterned in a dielectric layer 40. In the present example, electronic device 11 comprises a single power interconnect layer 44 having a thickness (along the Z-axis) greater than that of signal interconnect layers 22, as such, power interconnect layer 44 is also referred to herein as a thick power interconnect layer 44. For example, the range of thicknesses in signal interconnect layers 22 is typically less than about 400 nm (e.g., between about 50 nm and 350 nm), and the thickness of power interconnect layer 44 is typically greater than about 500 nm.

Reference is now made to the second set 27 of metal interconnect layers. In some embodiments, the set 27 comprises one or more power interconnect layers 32 having the higher electrical resistance (e.g., in the first range), and one or more (in the present example one) thick power interconnect layer(s) 33 with electrical resistance in the second range of resistances, i.e., lower resistance compared to that of power interconnect layers 32. In one embodiment, the thickness of power interconnect layer(s) 33 is greater than about 500 nm and the thickness of power interconnect layers 32 is between about 20 nm and 500 nm.

In some embodiments, electronic device 11 comprises a plurality of through-substrate vias traversing semiconductor substrate 10 between first side 17 and second side 18. The through-substrate vias comprise (i) signal through-substrate vias 24 configured for signal routing, and (ii) power through-substrate vias 25 configured for power distribution. In some embodiments, through-substrate vias 24 and 25 are configured to conduct data signals and electrical power, respectively, between (i) transistors 14, and (ii) first set 26 of metal interconnect layers and/or second set 27 of metal interconnect layers.

In some embodiments, one or more of through-substrate vias 24 and 25 are configured to conduct data signals and electrical power, respectively, between first set 26 of metal interconnect layers and/or second set 27 of metal interconnect layers. For example, through-substrate via 24, which is positioned in XY plane between transistors 14 and vias 25, is configured to conduct data signals between interconnect layers 22 and 32.

In some embodiments, electronic device 11 comprises a power delivery network 28 implemented in the second set 27 of metal interconnect layers, e.g., in power interconnect layers 32 and in thick power interconnect layer(s) 33. In some embodiments, first set 26 of metal interconnect layers comprises layers configured to route data signals (and optionally electrical power), and second set 27 of metal interconnect layers comprises layers configured to distribute electrical power. Typically, all the metal interconnect layers of sets 26 and 27 comprise metal lines made from copper or other metals such as aluminum or tungsten. For example, layers 22 that are in contact with transistors 14 and/or with through-substrate vias 24 and/or 25 may comprise tungsten or aluminum alloy, and the other layers of sets 26 and 27 are made from copper whose electrical resistance is lower compared to that of tungsten and aluminum alloy. In other embodiments, all layers are made from copper and the cross-sections (e.g., thickness along the Z-axis, and width in XY plane) determine the range of electrical resistances described above.

In some embodiments, thick power interconnect layer 44 from first set 26 of metal interconnect layers and thick power interconnect layer 33 from second set 27 of metal interconnect layers are positioned as outermost layers in the respective sets of the metal interconnect layers. In the present example, the outer surface of thick power interconnect layer 44 is approximately flush with a surface 37 of dielectric layer 40, and the outer surface of thick power interconnect layer 33 is approximately flush with a surface 38 of dielectric layer 30.

In some embodiments, electronic device 11 comprises multiple inductors formed in interconnect layers 44 and 33 configured to support circuit elements with reduced electrical resistance in first set 26 of metal interconnect layers and second set 27 of metal interconnect layers, respectively. The multiple inductors that are formed in interconnect layers 44 and 33 are configured to support circuit elements with reduced electrical resistance in each of the first set 26 of metal interconnect layers and the second set 27 of metal interconnect layers, respectively. Specifically, a front inductor 55a is formed in thick power interconnect layer 44 of first set 26 of metal interconnect layers, and a back inductor 55b is formed in thick power interconnect layer 33 of second set 27 of metal interconnect layers. In the present example, front inductor 55a and back inductor 55b are part of an analog circuit and are not vertically aligned with one another. In other words, front inductor 55a and back inductor 55b may be positioned in different areas within the XY plane of interconnect layers 44 and 33, respectively.

In some embodiments, substrate 10 and the one or more layers whose electrical resistance is in the first range of resistances (e.g., signal interconnect layers 22, and power interconnect layers 32) are arranged to provide electromagnetic shielding between front inductor 55a and back inductor 55b. In such embodiments, the intermediate layers between front inductor 55a and back inductor 55b are configured to prevent interferences between the electrical power conducted through inductors 55a and 55b. It is noted that in the example configuration of FIG. 1, electronic device 11 comprises one front inductor 55a and one back inductor 55b implemented in a section of electronic device 11. In other embodiments, a plurality of front inductors 55a may be implemented in the XY plane of interconnect layers 44 and/or a plurality of back inductors 55a may be implemented in the XY plane of interconnect layers 33 in broader sections of electronic device 11. As such, electronic device 11 may comprise sections having any suitable number of inductors 55a and 55b arranged along the respective XY planes in the front side and back side of device 11, respectively.

In other embodiments, in addition to or instead of inductors 55a and 55b, at least some interconnect layers 44 and 33 may be arranged in structures other than inductors and configured to serve as power interconnect layers within the digital circuits of a digital device. For example, the reduced electrical resistance of interconnect layers 44 and 33 may be leveraged for long-distance routing applications in purely digital electronic devices and could be implemented in electronic device 11 in certain embodiments.

In alternative embodiments, the reduced electrical resistance of interconnect layers 44 and 33 may be utilized as power interconnect layers in a mixed-signal device that integrates both analog and digital circuits within the same electronic device. This configuration may be implemented, for example, in electronic device 11.

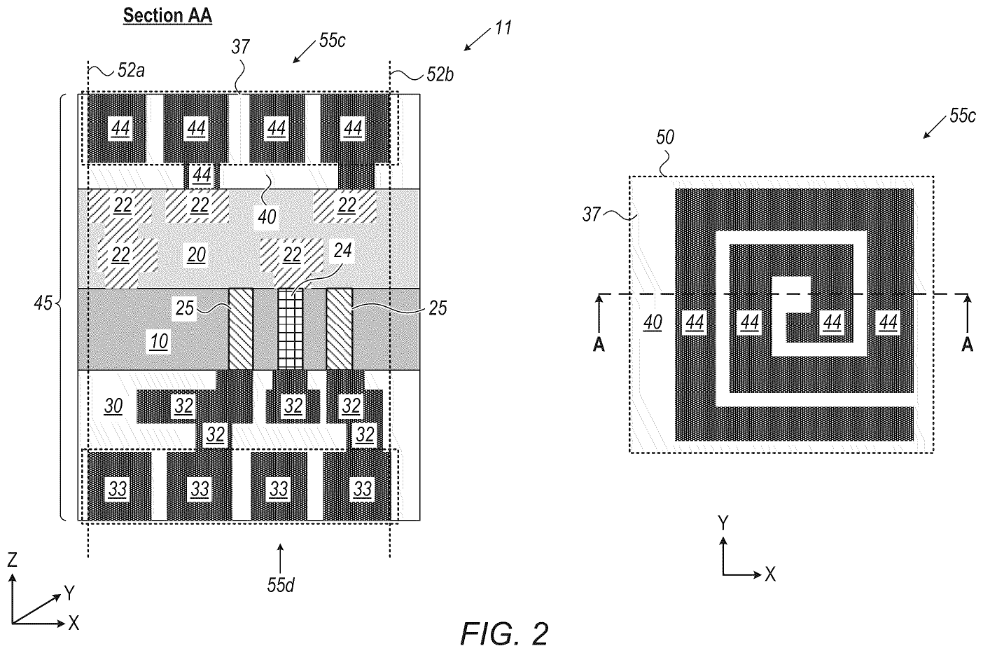

FIG. 2 is a cross-sectional view of a vertical stack 45 of an analog circuit implemented in another section of electronic device 11, in accordance with another embodiment that is described herein. In the context of the present disclosure and in the claims, the terms vertical stack, stacked configuration and grammatical variations thereof are used interchangeably. It is noted that the cross sectional structure of layers in FIG. 2 is similar to that of FIG. 1, but with a different arrangement of at least the inductors in the XY planes of the front side and the back side of electronic device 11. Moreover, transistors 14 are not shown in FIG. 2 but are typically implemented to enable the operation of the analog circuit (e.g., implemented in the vertical stack 45).

In some embodiments, vertical stack 45 (e.g., of the analog circuit) of electronic device 11 comprises one or more front inductors 55c implemented within thick power interconnect layer 44 on the front side, i.e., first side 17, and one or more back inductors 55b implemented within thick power interconnect layer 33 on the back side, i.e., second side 18. In the present example, this vertical stack 45 (e.g., of an analog circuit) of electronic device 11 shows a single front inductor 55c and a single back inductor 55d facing one another. In this configuration, front inductor 55c and back inductor 55d are arranged in a vertical stack 45 configuration with front inductor 55a in first set 26 of metal interconnect layers vertically aligned with back inductor 55b in second set 27 of metal interconnect layers. The vertical alignment is shown by a first alignment marker 52a and a second alignment marker 52b, which are not real and are provided in FIG. 2 to indicate the vertically aligned positions of front inductor 55c and back inductor 55d within the structure of this section in the vertical stack 45 of the analog circuit in electronic device 11. In some embodiments, the arrangement of inductors 55c and 55d in a stacked configuration with vertical alignment is configured to improve the performance of the analog circuit implemented in the vertical stack 45 compared to another analog circuits having all inductors arranged in one side of substrate 10. For example, having all inductors arranged, e.g., side-by-side, in interconnect layer 33 (or alternatively, in interconnect layer 44) of electronic device 11.

Reference in now made to an inset 50, which is a top view presenting the layout pattern of front inductor 55a in XY plane of surface 37 of dielectric layer 40. In some embodiments, front inductor 55a is implemented in thick power interconnect layer 44, which is patterned in dielectric layer 40. The top view of inset 50 illustrates an example arrangement of the structure of front inductor 55a. It is noted that dashed line AA illustrates the cross section of front inductor 55a as shown in the general view of FIG. 2.

In some embodiments, the structure described in FIGS. 1 and 2 enables separate optimization of layers for signal routing and power distribution, with the flexibility to implement power delivery network 28 primarily on one side (e.g., the back side) while maintaining high-performance signal routing on the other side (e.g., the front side) of electronic device 11. The arrangement allows for the implementation of analog circuits with inductors on both sides of semiconductor substrate 10, utilizing the intervening layers, such as dielectric layers 20, 30 and 40 and interconnect layers 22 and 32, as well as semiconductor substrate 10 itself, as electromagnetic shielding between components of electronic devices 11, for example, between inductors 55a and 55b of FIG. 1, and between inductors 55c and 55d of FIG. 2.

In some embodiments, at least one of (and typically all) inductors 55a-55d comprise High-Q inductors designed to have a high quality factor (Q) configured to exhibit low energy loss and high efficiency in various applications, such as radio frequency (RF) applications and high-frequency applications. Such High-Q inductors may be used, for example, in wireless communication, impedance matching, and resonant circuits.

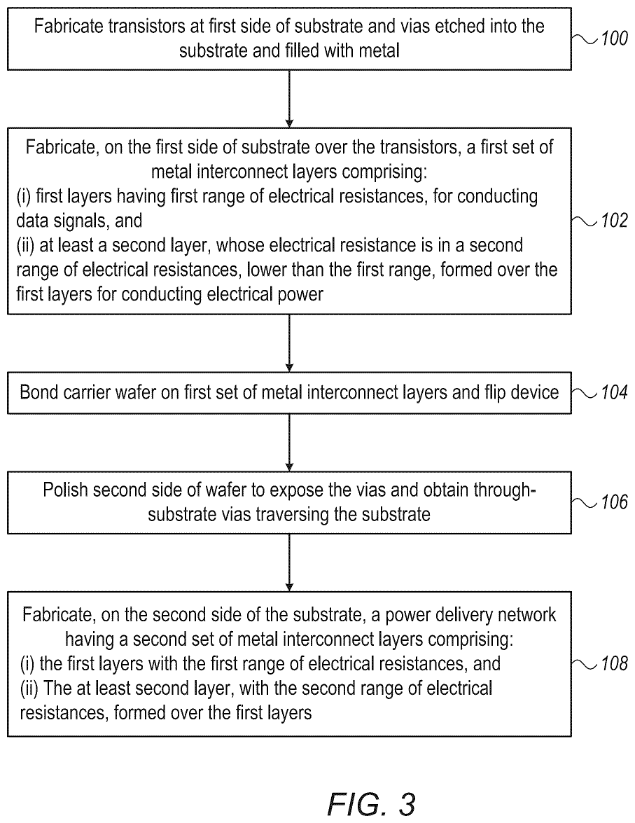

FIG. 3 is a flow chart that schematically illustrates a method for fabricating electronic device 11 and the analog circuit implemented in vertical stack 45, in accordance with an embodiment that is described herein. The method begins at a transistor and via fabrication step 100 with fabricating transistors 14 on first side 17 of substrate 10, and subsequently, etching vias 24 and 25 from first side 17 into substrate 10, and filling vias 24 and 25 with metal layers, such as copper or any other suitable electrical conducting material. It should be noted that, in step 100, the depth of vias 24 and 25 (e.g., between about 0.1 μm and 0.4 μm) is less than the initial thickness of substrate 10 (e.g., between about 0.8 mm and 1 mm before being polished as will be described below). Accordingly, vias 24 and 25 do not yet constitute through-substrate vias, as vias 24 and 25 do not extend completely through substrate 10 and one side of vias 24 and 25 is buried in substrate 10.

At a first set fabrication step 102, first set 26 of metal interconnect layers is formed on first side 17, which is the front side of substrate 10. The fabrication of first set 26 of metal interconnect layers comprises disposing dielectric layer 20 over first side 17, patterning multiple signal interconnect layers 22 in dielectric layer 20, disposing dielectric layer 40 over layers 20 and 22, and patterning one or more thick power interconnect layers 44 in a dielectric layer 40. It should be noted that a portion of the outermost power interconnect layer 44 is arranged in a pattern that forms front inductors 55a and 55c, as described in detail in FIGS. 1 and 2, respectively.

At a carrier bonding step 104, a carrier wafer or die (not shown) is bonded to surface 37 of the first set 26 of metal interconnect layers, after which the carrier wafer and substrate 10 are inverted (flipped upside-down).

At a via exposure step 106, the back side of substrate 10 is polished to a thickness between about 0.1 μm and 0.4 μm to expose the buried side of vias 24 and 25 formed in step 100 and to obtain through-substrate vias 24 and 25 traversing substrate 10 between first side 17 and second side 18. The structure and functionality of through-substrate vias 24 and 25 is described in detail in FIG. 1 above.

In other embodiments, the process sequence may be in a different order. For example, transistors 14 and the front side interconnects (e.g., first set 26 of metal interconnect) are formed. Subsequently, substrate 10 is flipped, and through-substrate vias 24 and 25 are formed in substrate 10 by etching through substrate 10 (which is polished to a thickness between 0.1 μm and 0.4 μm as described above) and filling through-substrate vias 24 and 25 with metal layers as described above.

At a second set fabrication step 108 that concludes the method, the carrier wafer is removed and the second set 27 of metal interconnect layers are formed on second side 18, which is the back side of substrate 10. The fabrication of second set 27 of metal interconnect layers comprises disposing dielectric layer 30 over second side 18, patterning one or more power interconnect layers 32 in dielectric layer 30, disposing an additional dielectric layer 30 over layers 30 and 32, and patterning one or more thick power interconnect layers 33 in the additional dielectric layer 30. It should be noted that a portion of the outermost power interconnect layer 33 is arranged in a pattern that forms back inductors 55b and 55d, as described in detail in FIGS. 1 and 2, respectively. Moreover, front inductors 55a and 55c and back inductors 55b and 55d are arranged in a stacked configuration (as described in FIGS. 1 and 2 above) with at least front inductor 55c and back inductor 55d being vertically aligned, as described in detail in FIG. 2 above.

It is noted that the embodiments described above are cited by way of example, and that the present invention is not limited to what has been particularly shown and described hereinabove. Rather, the scope of the present invention comprises both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An electronic device, comprising:
a semiconductor substrate;
a plurality of transistors formed on a first side of the semiconductor substrate;
a first set of metal interconnect layers formed on the first side of the semiconductor substrate; and
a second set of metal interconnect layers formed on a second side of the semiconductor substrate opposite to the first side,
wherein each of the first set of metal interconnect layers and the second set of metal interconnect layers comprises
(i) one or more layers whose electrical resistance is in a first range of resistances, and
(ii) at least one layer whose electrical resistance is in a second range of resistances, lower than the first range.

2. The electronic device according to claim 1, wherein:
the at least one layer configured to support circuit elements with reduced electrical resistance in the first set of metal interconnect layers comprises a first inductor of an analog circuit;
the at least one layer configured to support circuit elements with reduced electrical resistance in the second set of metal interconnect layers comprises a second inductor of the analog circuit; and
at least the one or more layers whose electrical resistance is in the first range of resistances are arranged to provide electromagnetic shielding between the first inductor and the second inductor.

3. The electronic device according to claim 1, wherein the first set of metal interconnect layers comprises layers configured to route data signals, and the second set of metal interconnect layers comprises layers configured to distribution electrical power.

4. The electronic device according to claim 1, further comprising a power delivery network implemented in the second set of metal interconnect layers.

5. The electronic device according to claim 1, wherein the at least one layer from each of the first set of metal interconnect layers and the second set of metal interconnect layers is positioned as an outermost layer in its respective set.

6. The electronic device according to claim 1, further comprising multiple inductors formed in the at least one layer configured to support circuit elements with reduced electrical resistance in each of the first set of metal interconnect layers and the second set of metal interconnect layers.

7. The electronic device according to claim 6, wherein the multiple inductors are arranged in a stacked configuration with at least a first inductor in the first set of metal interconnect layers vertically aligned with at least a second inductor in the second set of metal interconnect layers.

8. The electronic device according to claim 1, further comprising a plurality of through-substrate vias traversing the semiconductor substrate between the first side and the second side, the through-substrate vias being configured to conduct data signals and electrical power between (i) the plurality of transistors, and (ii) the first set of metal interconnect layers and the second set of metal interconnect layers.

9. The electronic device according to claim 8, wherein the plurality of through-substrate vias comprise first through-substrate vias for signal routing and second through-substrate vias for power distribution.

10. The electronic device according to claim 9, wherein at least one of the first through-substrate vias is configured to conduct the data signals between the first set of metal interconnect layers and the second set of metal interconnect layers.

11. A method for fabricating an electronic device, the method comprising:
forming a plurality of transistors on a first side of a semiconductor substrate;
forming a first set of metal interconnect layers on the first side of the semiconductor substrate; and
forming a second set of metal interconnect layers on a second side of the semiconductor substrate opposite to the first side,
wherein forming each of the first set of metal interconnect layers and the second set of metal interconnect layers comprises:
(i) forming one or more layers whose electrical resistance is in a first range of resistances, and
(ii) forming at least one layer whose electrical resistance is in a second range of resistances, lower than the first range.

12. The method according to claim 11, further comprising: (i) forming a first inductor of an analog circuit in the at least one layer with lower electrical resistance in the first set of metal interconnect layers; (ii) forming a second inductor of the analog circuit in the at least one layer with lower electrical resistance in the second set of metal interconnect layers; and (iii) arranging at least the one or more layers whose electrical resistance is in the first range of resistances to provide electromagnetic shielding between the first inductor and the second inductor.

13. The method according to claim 11, wherein forming the first set of metal interconnect layers comprises configuring layers to route data signals, and forming the second set of metal interconnect layers comprises configuring layers to distribute electrical power.

14. The method according to claim 11, further comprising implementing a power delivery network in the second set of metal interconnect layers.

15. The method according to claim 11, wherein forming the at least one layer with lower electrical resistance in each of the first set of metal interconnect layers and the second set of metal interconnect layers comprises positioning these layers as outermost layers in the respective sets of the metal interconnect layers.

16. The method according to claim 11, further comprising forming multiple inductors in the at least one layer with lower electrical resistance in each of the first set of metal interconnect layers and the second set of metal interconnect layers.

17. The method according to claim 16, wherein forming the multiple inductors comprises arranging the multiple inductors in a stacked configuration with at least a first inductor in the first set of metal interconnect layers vertically aligned with at least a second inductor in the second set of metal interconnect layers.

18. The method according to claim 11, further comprising: (a) forming a plurality of through-substrate vias traversing the semiconductor substrate between the first side and the second side, (b) configuring the through-substrate vias to conduct data signals and electrical power between (i) the plurality of transistors, and (ii) the first set of metal interconnect layers and the second set of metal interconnect layers, and (c) connecting at least one layer of the first set of metal interconnect layers to at least one layer of the second set of metal interconnect layers using the through-substrate vias.

19. The method according to claim 18, wherein forming the plurality of through-substrate vias comprises forming (i) first through-substrate vias configured for signal routing and (ii) second through-substrate vias configured for power distribution.

20. The method according to claim 19, wherein forming the first through-substrate vias comprises configuring at least one of the first through-substrate vias to conduct data signals between the first set of metal interconnect layers and the second set of metal interconnect layers.
